(19) United States
(12) Patent Application Publication
(10) Pub. No.: US 2009/0001585 A1
(43) Pub. Date: Jan. 1, 2009

(54) METHOD OF MANUFACTURING FLASH MEMORY DEVICE

(76) Inventor: Sung-Joong Joo, Yongin-si (KR)

Correspondence Address: SHERR & VAUGHN, PLLC, 620 HERNDON PARKWAY, SUITE 200, HERNDON, VA, 20170, US

(21) Appl. No.: 12/143,862

(22) Filed: Jun. 23, 2008

(30) Foreign Application Priority Data
Jun. 26, 2007 (KR) 10-2007-0062647

(51) Int. Cl. H01L 21/768; H01L 23/48

(52) U.S. Cl. 257/751; 438/653; 257/E21.584; 257/E23.01

(57) ABSTRACT

A method of manufacturing a flash memory that can include forming a titanium nitride (TiN) layer on the pre-metal dielectric having the via hole and then forming a TiSiN layer by injecting silane (SiH₄) gas on a semiconductor substrate having the titanium nitride layer; and then forming a contact by filling the via hole having the TiSiN layer.

The present application claims priority under 35 U.S.C. §119 and 35 U.S.C. §365 to Korean Patent Application No. 10-2007-0062647 (filed on Jun. 26, 2007), which is hereby incorporated by reference in its entirety.

### BACKGROUND

A flash memory device is a non-volatile memory medium capable of retaining its stored data even when no power is applied and also has various advantages in processing of writing, reading, or erasing data at high speed. Accordingly, flash memory devices are widely used as data storages such as a personal computer (PC) basic input/output system (BIOS), a set-top box, a printer, and a network server. Flash memory devices have current application in digital cameras and cellular phones.

However, as flash memory devices have become highly integrated, the spatial distance between gates of the flash memory device have become smaller or narrower. Therefore, the use of dielectric structure such as an oxide-nitride-oxide (ONO) structure for forming a spacer is reduced or a spacer itself is removed in order to reduce the spatial distance between gates of the flash memory device. Additionally, when the flash memory is programmed or erased, the fact that electrons generated in a pre-metal dielectric have an effect on a threshold voltage Vₜ of a gate becomes an issue. The electrons in the pre-metal dielectric are generated by a plasma process or a thermal treatment process after forming a gate.

### SUMMARY

Embodiments relate to a method of manufacturing a flash memory device that can include at least one of the following steps: forming a gate on and/or over a semiconductor substrate; and then forming a spacer on a sidewall of the gate; forming a pre-metal dielectric having a via hole on and/or over the semiconductor substrate having the gate and the spacer; and then forming a titanium nitride (TiN) layer on and/or over the pre-metal dielectric having the via hole; and then forming a TiN-containing silicon (TiSiN) layer by injecting silane (SiH₄) gas into the semiconductor substrate having the titanium nitride layer; and then forming a contact by filling the via hole having the TiSiN layer.

Embodiments relate to a method of manufacturing a flash memory device that can include at least one of the following steps: forming a gate on a semiconductor substrate; and then forming a spacer having a multi-layered dielectric structure on a sidewall of the gate; and then removing an outermost layer of the spacer having the multi-layered dielectric structure; and then forming a pre-metal dielectric layer having a via hole on the semiconductor substrate including the gate and the spacer; and then forming a titanium nitride-containing silicon (TiSiN) layer on the pre-metal dielectric layer including the via hole; and then forming a contact in the via hole and on the TiSiN layer.

Embodiments relate to a flash memory device that can include at least one of the following: a gate formed on a semiconductor substrate; a spacer formed on a sidewall of the gate; a pre-metal dielectric layer having a via hole formed on the semiconductor substrate including the gate and the spacer; a titanium nitride-containing silicon (TiSiN) layer formed on the pre-metal dielectric layer including the via hole; and a contact formed in the via hole and on the TiSiN layer.

### DRAWINGS

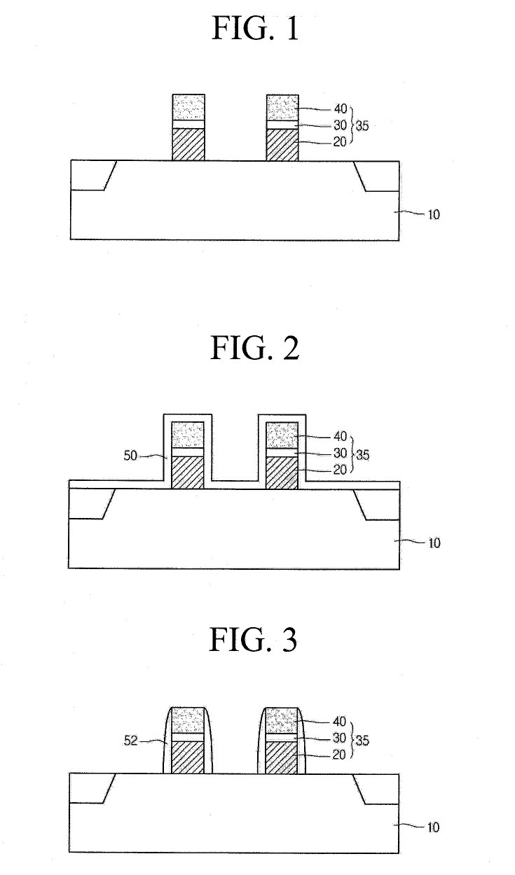

Example FIGS. 1 to 19 illustrate a method of manufacturing a flash memory device in accordance with embodiments.

### DESCRIPTION

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

In the following description, it will be understood that when a layer (or film) is referred to as being “on and/or over” another layer, it can be directly or indirectly on the another layer. The thickness or size of each layer may be exaggerated, omitted, or schematically illustrated for convenience and clarity of description. The size of each component does not entirely reflect its actual size.

As illustrated in example FIG. 1, a flash memory device in accordance with embodiments may include gate 35 may be formed on and/or over semiconductor substrate 10. Gate 35 may include first polysilicon pattern 20, oxide-nitride-oxide (ONO) layer pattern 30 and second polysilicon pattern 40. First polysilicon pattern 20 may serve as a floating gate and second polysilicon pattern 40 may serve as a control gate. ONO layer pattern 30 may be formed by annealing and patterning a first oxide layer, a nitride layer and a second oxide layer (which are sequentially stacked) and serves to insulate the top and the bottom. As illustrated in example FIG. 2, spacer layer 50 may be formed on and/or over semiconductor substrate 10 including gate 35. Spacer layer 50 may be formed of an ONO layer including a sequentially-stacked structure of a first oxide layer, a nitride and second oxide layer, but is not limited thereto. For example, spacer layer 50 may have an oxide-nitride (ON) structure. As illustrated in example FIG. 3, an etching process may then be performed on spacer layer 50 to form spacers 52 at both sides of gate 35.

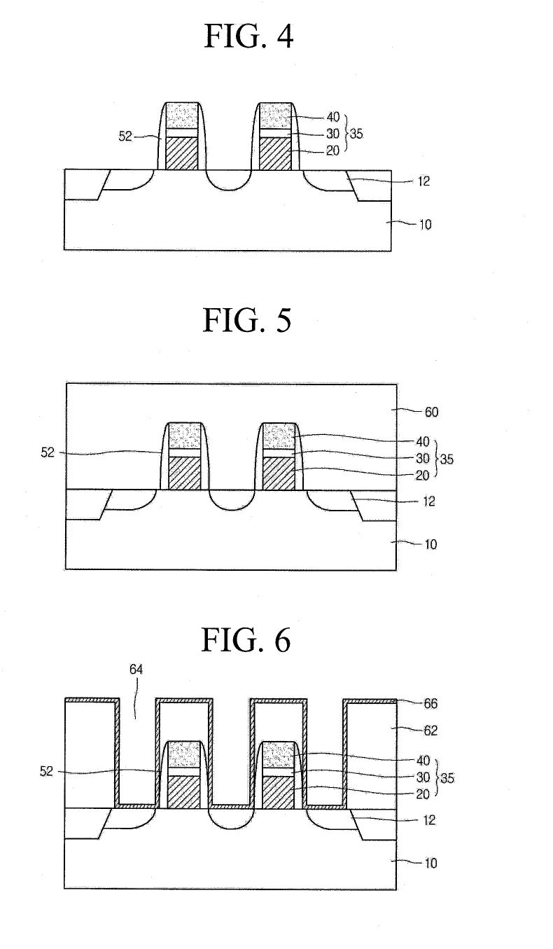

As illustrated in example FIG. 4, an ion implantation process may then be performed by using gate 35 and spacer 52 as a mask in order to form source/drain regions 12 in semiconductor substrate 10. As illustrated in example FIG. 5, pre-metal dielectric layer 60 may then be formed on and/or over semiconductor substrate 10 including gate 35 and spacer 52 by using tetra-ethyl-ortho-silicate (TEOS) and undoped silicate glass (USG). As illustrated in FIG. 6, a plurality of via holes 64 may then be formed at a position where a contact is to be formed. Via holes 64 may be formed exposing source/drain regions 12 of semiconductor substrate 10. Barrier metal layer 66 may then be formed on and/or over semiconductor substrate 10 including pre-metal dielectric 62, via hole 64 and source/drain regions 12. Via hole 64 may be used later in order to form a contact plug by filling a metal material, and a metal layer such as a titanium (Ti) layer on and/or over barrier metal 66 by performing a chemical vapor deposition (CVD) process.

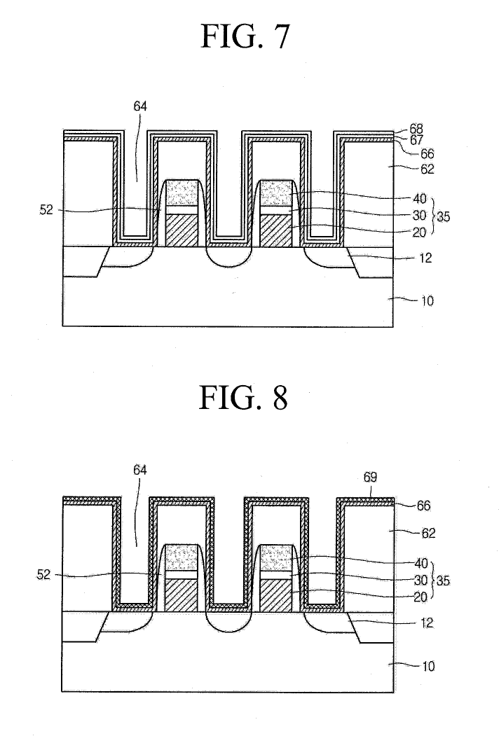

As illustrated in example FIG. 7, first titanium nitride layer 67 and second titanium nitride layer 68, each having a thickness ranging from between 15 Å to 25 Å, may then be formed on and/or over pre-metal dielectric layer 62 including barrier metal layer 66 and via hole 64. First titanium nitride layer 67 and second titanium nitride layer 68 may be formed through a CVD process using tetrakis-dimethyl-amido-titanium (TDMAT) as a source as follows. First, a heat process of applying heat for a time of over 15 sec and at a pressure of 10 Torr may be performed on pre-metal dielectric layer 62 including barrier metal layer 66 in order to easily perform a subsequent process for nitride titanium deposition. After finishing the heat process, a first thermal treatment process may then be performed to form first titanium nitride layer 67 having a thickness of between 15 Å to 25 Å on and/or over pre-metal dielectric 62 including barrier metal layer 66 and via hole 64. The first thermal treatment process may then be performed on first titanium nitride layer 67 for a time of between 5 sec to 40 sec at a temperature of 250° C. to 350° C. and at a pressure of between 3 Torr to 15 Torr. A second heat process may then be performed at a time length of 15 sec and at a pressure of 10 Torr to easily perform a subsequent process of titanium nitride deposition. After finishing the second heating process, a second thermal treatment process may then be performed to form second titanium nitride layer 68 having a thickness of between 15 Å to 25 Å on and/or over first titanium nitride layer 67. The second thermal treatment process may be performed on second titanium nitride layer 68 for a time of between 5 sec to 40 sec, a temperature of between 250° C. to 350° C. and at a pressure of between 3 Torr to 15 Torr. Silane (SiH₄) gas may then be injected on and/or over second nitride titanium layer 68 and then a plasma treatment or high temperature heat treatment may then be performed to form TiN-containing silicon (TiSiN) layer 69.

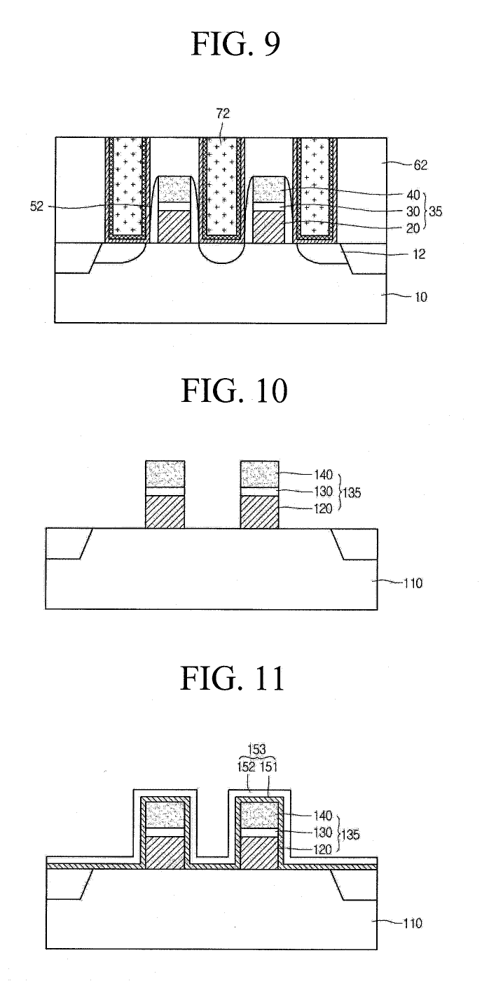

As illustrated in example FIG. 8, TiSiN layer 69 may be formed on and/or over pre-metal dielectric layer 62 including barrier metal layer 66. The thermal treatment process using silane (SiH₄) gas may be performed for a time of between 3 sec to 10 sec and a temperature of between 250° C. to 350° C. In accordance with embodiments, when a titanium nitride layer is formed, a process may be performed twice using first titanium nitride layer 67 and second titanium nitride layer 68 to form a double layer. However, a single titanium nitride layer having a thickness of between 30 Å to 50 Å may be used to form TiSiN layer 69 by performing a thermal treatment process using silane (SiH₄) gas one the single titanium nitride layer. TiSiN layer 69 may have a dense structure to prevent diffusion of copper (Cu) ions when metal wiring is formed during a subsequent process. Since electron generation can be prevented by a subsequent plasma or thermal treatment process, electrons generated in a pre-metal dielectric does not affect a threshold voltage Vₜ during a program or erase operation of a gate. As illustrated in example FIG. 9, a metal material may then be formed on and/or over pre-metal dielectric 62 including barrier metal layer 66 and TiSiN layer 69. A planarization process may then be performed to form contact plug 72 in via hole 64 and on and/or over TiSiN layer 69.

As illustrated in example FIG. 10, a flash memory device in accordance with embodiments may include gate 135 formed on and/or over semiconductor substrate 110 and may include first polysilicon pattern 120, ONO layer pattern 130 and second polysilicon pattern 140. First polysilicon pattern 120 may serve as a floating gate and second polysilicon pattern 140 may serve as a control gate. ONO layer pattern 130 may be formed by annealing and patterning a first oxide layer, a nitride layer and a second oxide layer (which are sequentially stacked) and serves to insulate the top and the bottom. As illustrated in example FIG. 11, spacer layer 153 having an ON structure including oxide layer 151 and nitride layer 152 may then be formed on and/or over semiconductor substrate 110 including gate 135. Spacer layer 153 may alternatively be formed of an ONO structure. As illustrated in example FIG. 12, an etching process may then be performed on spacer layer 153 to form spacers 163 at both sides of gate 135. Spacers 163 may be composed of oxide layer 161 and nitride layer 162.

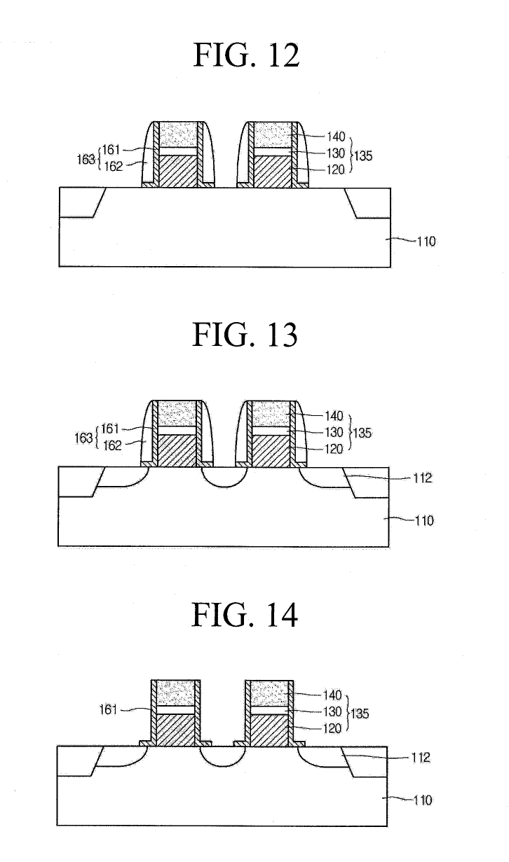

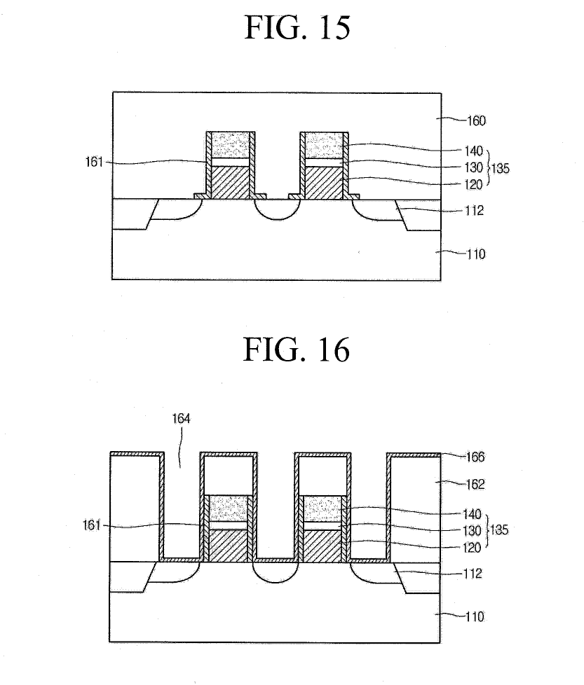

As illustrated in example FIG. 13, an ion implantation process may then be performed by using gate 135 and the spacer 163 as a mask to form source/drain regions 112. As illustrated in example FIG. 14, after forming source/drain regions 112, a dielectric layer formed at the outermost of spacer 163 is removed. Because spacer 163 has an ON structure in accordance with embodiments, nitride layer 162 can be removed. When the ONO layer is used as spacer 163, the second oxide layer formed at the outermost region can be removed. Removal of nitride layer 162 formed at the outermost region of spacer 163 may be performed through wet etching. Accordingly, a spatial interval or distance between gates 135 may be increased by removing a portion of spacer 163. As illustrated in example FIG. 15, pre-metal dielectric layer 160 may then be formed on and/or over semiconductor substrate 110 including gate 135 and spacer 163 by using TEOS and USG.

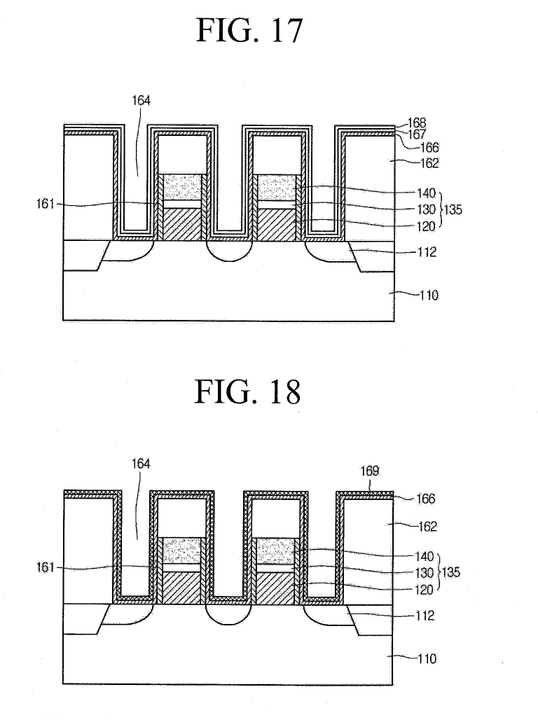

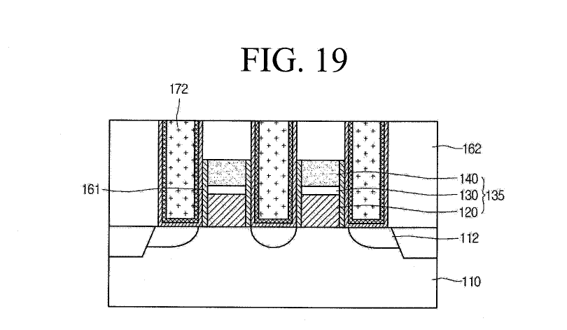

As illustrated in example FIG. 16, a plurality of via holes 164 may then be formed at a position where contacts are to be formed. Barrier metal layer 166 may then be formed on and/or over pre-metal dielectric layer 62 including via holes 164. Via holes 164 may be used later in order to form a contact plug by filling a metal material and a titanium (Ti) layer formed by performing a CVD process on barrier metal layer 166. As illustrated in example FIG. 17, first titanium nitride layer 167 and second titanium nitride layer 168 may be sequentially formed on pre-metal dielectric 164 including via holes 164 and barrier metal layer 166. First titanium nitride layer 167 and second titanium nitride layer 168 may each have a thickness of between a 15 Å and 25 Å. Processes of forming first titanium nitride layer 167 and second titanium nitride layer 168 through a CVD process using TDMAT are as follows.

A heat process may be applied for 15 sec at a pressure of 10 Torr on pre-metal dielectric layer 162 including barrier metal layer 166 in order to easily perform a subsequent process of titanium nitride deposition. After finishing the heating process, a first thermal treatment process may then be performed to form first titanium nitride layer 167 having a thickness of between 15 Å to 25 Å on and/or over pre-metal dielectric 162 including via hole 164 and barrier metal layer 166. The first thermal treatment process may be performed on first nitride titanium 167 at a time of between 5 sec to 40 sec, a temperature of between 250° C. to 350° C. and a pressure of between 3 Torr to 15 Torr. A second heat process may be applied for a time of 15 sec at a pressure of 10 Torr on first titanium nitride layer 167 to easily perform a subsequent process of titanium nitride deposition. After finishing the second heating process, a second thermal treatment process may be performed to form second titanium nitride layer 168 having a thickness of between 15 Å to 25 Å on and/or over first titanium nitride layer 167. The second thermal treatment process may be performed on second nitride titanium 168 at a time of between 5 sec to 40 sec, a temperature of between 250° C. to 350° C. and a pressure of between 3 Torr to 15 Torr. Silane (SiH₄) gas may then be injected on and/or over second titanium nitride layer 168 and plasma treatment or high temperature heat treatment may then be performed. As illustrated in example FIG. 18, TiSiN layer 169 having a silicon (Si) group is thereby formed on and/or over pre-metal dielectric layer 162. The thermal treatment process using silane (SiH₄) gas may be performed at a time of between 3 sec to 10 sec at a temperature of between 250° C. to 350° C.

According to embodiments, a double titanium nitride layer may be formed including first titanium nitride layer 167 and second nitride titanium layer 167 and 168. However, a single titanium nitride layer having a thickness of between 30 Å to 50 Å may be formed by performing the thermal treatment process using silane (SiH₄) gas. The formed TiSiN layer 169 has a dense structure to prevent diffusion of copper (Cu) ions when metal wiring is formed during a subsequent process. Since electron generation can be prevented by a subsequent plasma or thermal treatment process, electrons generated in a pre-metal dielectric does not affect a threshold voltage Vₜ during a program or erase operation of a gate. As illustrated in example FIG. 19, after forming a metal material on and/or over pre-metal dielectric 162 including barrier metal layer 166 and TiSiN layer 169, a planarization process may then be performed to form contact plug 172.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a flash memory device comprising:
forming a gate on a semiconductor substrate; and then
forming a spacer on a sidewall of the gate; and then
forming a pre-metal dielectric layer having a via hole on the semiconductor substrate including the gate and the spacer; and then
forming a titanium nitride layer on the pre-metal dielectric including the via hole; and then
forming a titanium nitride-containing silicon (TiSiN) layer by exposing the titanium nitride layer to silane (SiH₄) gas; and then
forming a contact by filling the via hole including the TiSiN layer.

2. The method of claim 1, further comprising, before forming the titanium nitride layer:
forming a barrier metal layer on the pre-metal dielectric layer including the via hole.

3. The method of claim 2, wherein the barrier metal layer comprises titanium.

4. The method of claim 3, further comprising, after forming the barrier metal layer and before forming the titanium nitride layer:
performing a first heat treatment process on the semiconductor substrate including the barrier metal layer.

5. The method of claim 1, wherein forming the titanium nitride layer comprises:
forming a first titanium nitride layer on the pre-metal dielectric including the via hole; and then
forming a heat treatment process on the first titanium nitride layer; and then
forming a second titanium nitride layer on the first titanium nitride layer.

6. The method of claim 5, wherein the first titanium nitride layer and the second titanium nitride layer are formed having a thickness of between 15 Å and 25 Å.

7. The method of claim 1, wherein the titanium nitride layer is formed with a thickness of between 30 Å to 50 Å.

8. A method comprising:
forming a gate on a semiconductor substrate; and then
forming a spacer having a multi-layered dielectric structure on a sidewall of the gate; and then
removing an outermost layer of the spacer having the multi-layered dielectric structure; and then
forming a pre-metal dielectric layer having a via hole on the semiconductor substrate including the gate and the spacer; and then
forming a titanium nitride-containing silicon (TiSiN) layer on the pre-metal dielectric layer including the via hole; and then
forming a contact in the via hole and on the TiSiN layer.

9. The method of claim 8, wherein removing the outermost layer of the spacer is performed by a wet etching process.

10. The method of claim 8, wherein forming the TiSiN layer comprises:
forming a titanium nitride layer on the pre-metal dielectric layer including the via hole; and then
exposing the titanium nitride layer to silane gas.

11. The method of claim 10, wherein the titanium nitride layer is formed with a thickness of between 30 Å to 50 Å.

12. The method according to claim 10, wherein forming the titanium nitride layer comprises:
forming a first titanium nitride layer on the pre-metal dielectric including the via hole; and then
forming a heat treatment process on the first titanium nitride layer; and then
forming a second titanium nitride layer on the first titanium nitride layer.

13. The method of claim 12, wherein the first titanium nitride layer and the second titanium nitride layer are formed having a thickness of between 15 Å and 25 Å.

14. The method of claim 8, further comprising, before forming the titanium nitride layer:
forming a barrier metal layer on the pre-metal dielectric layer including the via hole.

15. The method of claim 14, wherein the barrier metal layer comprises titanium.

16. The method of claim 15, further comprising, after forming the barrier metal layer and before forming the titanium nitride layer:
performing a first heat treatment process on the semiconductor substrate including the barrier metal layer.

17. The method of claim 8, wherein forming the spacer comprises:
forming a spacer layer by sequentially forming a first oxide layer, a nitride layer and a second nitride layer on the semiconductor substrate including the gate; and then
performing an etching process on the spacer layer.

18. The method of claim 17, wherein removing the outermost layer of the spacer comprises removing the second nitride layer.

19. The method of claim 8, wherein forming the TiSiN layer comprises:
performing a first heat process on the pre-metal dielectric layer; and then
performing a first thermal treatment process to form a first titanium nitride layer on the pre-metal dielectric layer including the via hole; and then
performing a second heat process on the first titanium nitride layer; and then
performing a second thermal treatment process to form a second titanium nitride layer on the first titanium nitride layer; and then
exposing the second titanium nitride layer to silane gas.

20. An apparatus comprising:
a gate formed on a semiconductor substrate;
a spacer formed on a sidewall of the gate;
a pre-metal dielectric layer having a via hole formed on the semiconductor substrate including the gate and the spacer;
a titanium nitride-containing silicon (TiSiN) layer formed on the pre-metal dielectric layer including the via hole; and
a contact formed in the via hole and on the TiSiN layer.
